(19) United States
(12) Patent Application Publication
(10) Pub. No.: US 2017/0047305 A1
(43) Pub. Date: Feb. 16, 2017

(54) PACKAGING ARRANGEMENTS INCLUDING A SERIALIZING DRAM INTERFACE DIE

(71) Applicant: Marvell World Trade Ltd., St. Michael (BB)

(72) Inventors: Chenglin Liu, Cupertino, CA (US); Shiann-Ming Liou, Campbell, CA (US)

(73) Assignee: Marvell World Trade Ltd.

(21) Appl. No.: 15/228,859

(22) Filed: Aug. 4, 2016

Related U.S. Application Data
(60) Provisional application No. 62/204,781, filed on Aug. 13, 2015.

(51) Int. Cl. H01L 23/00

(52) U.S. Cl. CPC H01L 24/32; H01L 24/48; H01L 24/85; H01L 24/83; H01L 2924/1436

(57) ABSTRACT

Embodiments provide a packaging arrangement that comprises a package substrate. A random access memory die is coupled to the package substrate and a serializing random access memory interface die coupled to (i) the package substrate and (ii) the random access memory die.

### CROSS REFERENCE TO RELATED APPLICATIONS

This claims priority to U.S. Provisional Patent Application No. 62/204,781, filed on Aug. 13, 2015, which is incorporated herein by reference in its entirety.

### TECHNICAL FIELD

Embodiments of the present disclosure relate to semiconductor packaging arrangements, and in particular to packaging arrangements that include a serializing DRAM interface die.

### BACKGROUND

Random access memory (such as dynamic random access memory (DRAM)) interface speeds continue to increase to higher and higher levels. The number of signals to and from the memory are generally high and the data/address signals are single-ended. Thus, the DRAM interface may become the bottleneck of routing of signals at all levels, especially the printed circuit board (PCB) and packaging levels. This generally requires more routing resources such as higher layer counts to route signals, which translates into high costs for PCBs and packaging.

### SUMMARY

In various embodiments, the present disclosure provides a packaging arrangement that comprises a package substrate. A random access memory die is coupled to the package substrate and a serializing random access memory interface die coupled to (i) the package substrate and (ii) the random access memory die.

In various embodiments, the present disclosure also provides a method that comprises providing a package substrate. A random access memory die is coupled to the package substrate, and a serializing random access memory interface die is coupled to (i) the package substrate and (ii) the random access memory die.

### BRIEF DESCRIPTION OF THE DRAWINGS

Embodiments of the present disclosure will be readily understood by the following detailed description in conjunction with the accompanying drawings. To facilitate this description, like reference numerals designate like structural elements. Various embodiments are illustrated by way of example and not by way of limitation in the figures of the accompanying drawings.

FIG. 1A schematically illustrates a packaging arrangement for a random access memory die and a serializing random access memory interface die.

FIG. 1B schematically illustrates another packaging arrangement for a random access memory die and a serializing random access memory interface die.

FIG. 1C schematically illustrates another packaging arrangement for two random access memory dies and a serializing random access memory interface die.

FIG. 2 is a flow diagram of an example method for making a packaging arrangement for a random access memory die and a serializing random access memory interface die.

### DETAILED DESCRIPTION

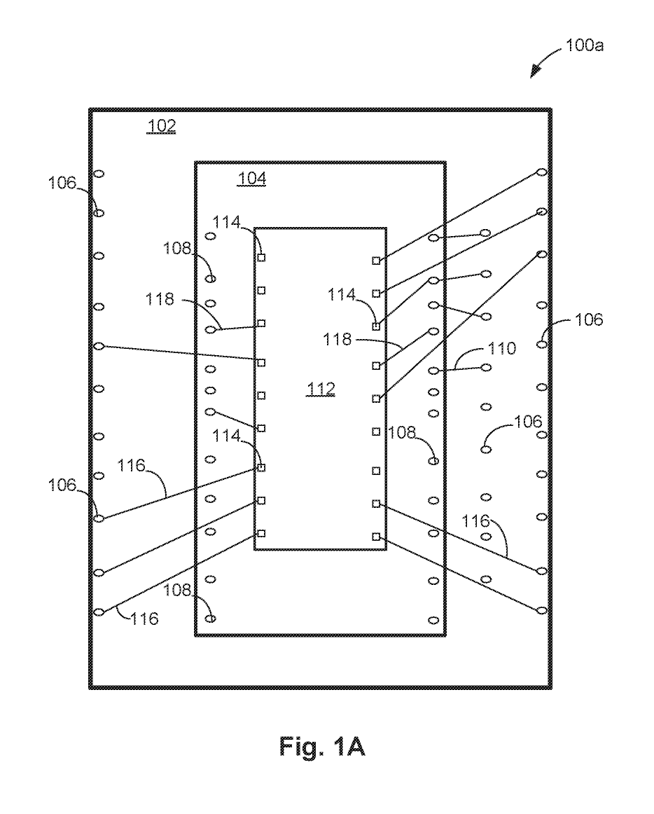

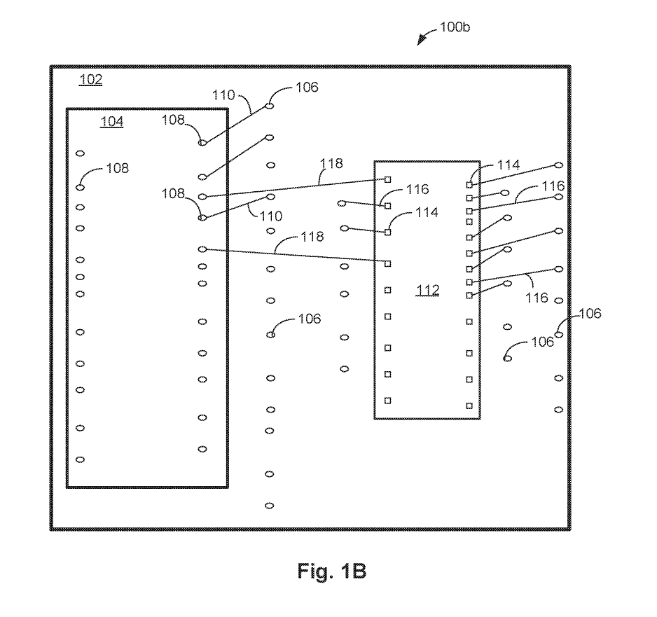

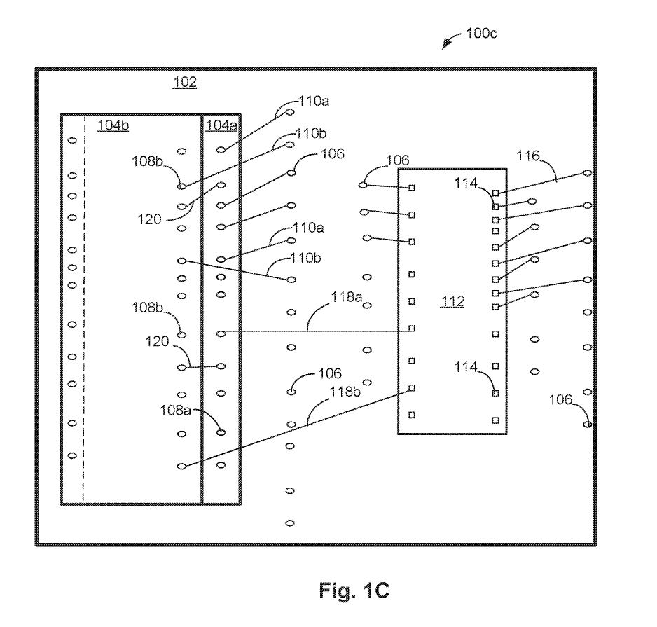

FIG. 1A schematically illustrates a packaging arrangement 100a that includes a package substrate 102. The packaging arrangement 100a further includes a die 104 configured as a random access memory die. In embodiments, the random access memory die is configured as a dynamic random access memory (DRAM) die. The DRAM die 104 is coupled to the package substrate 102. The DRAM die 104 can be attached to the package substrate 102 via, for example, flip chip attachment, wire bonding, etc. In embodiments where the DRAM die 104 is wire bond attached to the package substrate 102, an adhesive, epoxy, solder, etc., may be used to physically attach the DRAM die 104 to the package substrate 102.

The package substrate 102 includes wire bond fingers or pads 106 to allow for wire bond connections. Likewise, the DRAM die 104 includes wire bond fingers or pads 108 to allow for wire bond connections. Wires 110 provide coupling between the bond fingers 106 and 108, thereby allowing the DRAM die 104 to be coupled to the package substrate 102 to allow for the exchange of signals therebetween.

The packaging arrangement 100a further includes a serializing DRAM interface die 112. In the embodiment of FIG. 1A, the serializing DRAM interface die 112 is located on top of the DRAM die 104. The serializing DRAM interface die 112 can be flip chip attached to the DRAM die 104 or wire bond attached to the DRAM die 104. The serializing DRAM interface die 112 may be physically attached to the DRAM die 104 utilizing an adhesive, epoxy, solder, etc. The serializing DRAM interface die 112 includes wire bond fingers or pads 114 to allow for wire bond connections to the package substrate 102 and/or the DRAM die 104. Wires 116 and 118 provide coupling between the bond fingers 114 and 106, 108, respectively, thereby allowing the serializing DRAM interface die 112 to be coupled to the package substrate 102 and/or the DRAM die 104 to allow for the exchange of signals therebetween.

In embodiments, the package substrate 102 includes one or more redistribution layers (RDLs) (not illustrated). The RDLs can be utilized to route signals within the package substrate 102 between the DRAM die 104 and the serializing DRAM interface die 112. Thus, in embodiments, the wire bonding fingers 106 on the package substrate 102 can be utilized to receive signals from the DRAM die 104 and the serializing DRAM interface die 112 through corresponding wires 110, 116. The signals can be routed through one or more RDLs and provided to other wire bond fingers 106. The signals can then be provided to the DRAM die 104 and the serializing DRAM interface die 112 through corresponding wires 110, 116. The wire bond fingers 106 can also be utilized to provide power and ground signals to the DRAM die 104 and the serializing DRAM interface die 112 through corresponding wires 110, 116. Additionally, wires 118 can be used to directly couple wire bond fingers 108 on the DRAM die 104 with wire bond fingers 114 on the serializing DRAM interface 112 to allow signal exchange directly between the DRAM die 104 and the serializing DRAM interface die 112. Bond pads (not illustrated) may also be included on a surface of the DRAM die 104 to allow for direct coupling via solder to the package substrate 102 for signal exchange therebetween. Likewise, the serializing DRAM interface die 112 may include bond pads (not illustrated) on a surface to allow for direct coupling via solder to the DRAM die 104 for signal exchange therebetween.

FIG. 1B schematically illustrates a packaging arrangement 100b wherein the DRAM die 104 and the serializing DRAM interface die 112 are coupled to and located on the package substrate 102 in a side-by-side relationship. The DRAM die 104 can be coupled to the package substrate 102 via flip-chip attachment or wire bond coupling. An adhesive, epoxy, solder, etc., may be used to physically attach the DRAM die 104 to the package substrate 102. The serializing DRAM interface die 112 can be coupled to the package substrate 102 via flip-chip attachment or wire bond coupling. An adhesive, epoxy, solder, etc., may be used to physically attach the serializing DRAM interface die 112 to the package substrate 102. Bond pads (not illustrated) may also be included on a surface of the DRAM die 104 and/or the serializing DRAM interface die 112 to allow for direct coupling via solder to the package substrate 102 for signal exchange therebetween.

FIG. 1C schematically illustrates a packaging arrangement 100c that includes a first DRAM die 104a and a second DRAM die 104b. More DRAM dies 104 may be included if desired. In the embodiment of FIG. 1C, the first and second DRAM dies 104a, 104b are stacked on top of one another and the first DRAM die 104a is attached to the package substrate 102. In other embodiments, the first and second DRAM dies 104a, 104b are side by side and both attached to the package substrate 102. The serializing DRAM interface die 112 is located and coupled to the package substrate 102 beside the two stacked DRAM dies 104a, 104b. In embodiments where the first and second DRAM dies 104a, 104b are side by side, the serializing DRAM interface die 112 may be located beside one of the DRAM dies 104a, 104b, on top of one of the DRAM dies 104a, 104b, or in between the DRAM dies 104a, 104b.

The first DRAM die 104a can be coupled to the package substrate 102 via flip-chip attachment or wire bond coupling. An adhesive, epoxy, solder, etc., may be used to physically attach the first DRAM die 104a to the package substrate 102. The second DRAM die 104b can be coupled to the first die 104a or the package substrate 102 via flip-chip attachment or wire bond coupling. An adhesive, epoxy, solder, etc., may be used to physically attach the second DRAM die 104b to the package substrate 102. The serializing DRAM interface die 112 can be coupled to the package substrate 102 via flip-chip attachment or wire bond coupling. An adhesive, epoxy, solder, etc., may be used to physically attach the serializing DRAM interface die 112 to the package substrate 102. Bond pads (not illustrated) may also be included on a surface of the DRAM dies 104a, 104b and/or the serializing DRAM interface die 112 to allow for direct coupling via solder to the package substrate 102 for signal exchange therebetween. Wires 116a, 118a can be used to couple bond pads 108a on the first DRAM die 104a to bond pads 106, 114 on the package substrate 102 or the serializing DRAM interface die 112, respectively, while wires 116b, 118b can be used to couple bond pads 108b on the second DRAM die 104b to bond pads 106, 114 on the package substrate 102 or the serializing DRAM interface die 112, respectively. Wires 120 can be used to couple bond pads 108b on the second DRAM die 104b to bond pads 108a on the first DRAM die 104a.

Thus, in accordance with various embodiments, high speed differential signals may be routed in traditional low cost PCBs and packages. Serializing the DRAM interface by converting many single-ended signals to high speed differential signals in one package with one or more DRAM dies can solve routing issues of the traditional DRAM interface. The signal count is thus significantly reduced and routing resources may be significantly saved.

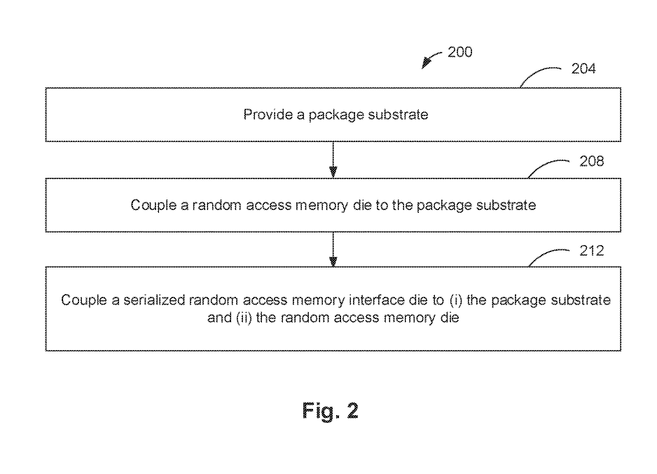

FIG. 2 is a flow diagram of an example method 200 for making a packaging arrangement, e.g., packaging arrangements 100a, 100b and 100c illustrated in FIGS. 1A, 1B and 1C, respectively, for a random access memory die and a serializing random access memory interface die.

At 204, a package substrate, e.g., package substrate 102, is provided. At 208, a random access memory die, e.g., DRAM die 104, is coupled to the package substrate. At 212, a serializing random access memory interface die, e.g., serializing DRAM interface die 112, to (i) the package substrate and (ii) the random access memory die.

Further aspects of the present invention relate to one or more of the following clauses.

Clause 1. A packaging arrangement comprising:

a package substrate;

a random access memory die coupled to the package substrate; and

a serializing random access memory interface die coupled to (i) the package substrate and (ii) the random access memory die.

Clause 2. The packaging arrangement of clause 1, wherein the serializing random access memory interface die is located on the random access memory die.

Clause 3. The packaging arrangement of clause 1, wherein the serializing random access memory interface die is located on the package substrate beside the random access memory die located on the package substrate.

Clause 4. The packaging arrangement of clause 1, wherein:

the random access memory die is a first random access memory die; and

the packaging arrangement further comprises a second random access memory die coupled to (i) the package substrate and (ii) the first random access memory die.

Clause 5. The packaging arrangement of clause 4, wherein the second random access memory die is located on the first random access memory die.

Clause 6. The packaging arrangement of clause 4, wherein the second random access memory die is located on the package substrate beside the first random access memory die located on the package substrate.

Clause 7. The packaging arrangement of clause 4, wherein the second random access memory die is directly coupled to the serializing random access memory interface die.

Clause 8. The packaging arrangement of clause 1, wherein the random access memory die is directly coupled to the serializing random access memory interface die.

Clause 9. The packaging arrangement of clause 1, wherein the random access memory die is flip-chip attached to the package substrate.

Clause 10. The packaging arrangement of clause 1, wherein the random access memory die is wire bonded to (i) the package substrate and (ii) the serializing random access memory interface die.

Clause 11. The packaging arrangement of clause 1, wherein the serializing random access memory interface die is flip-chip attached to the package substrate.

Clause 12. The packaging arrangement of clause 1, wherein the serializing random access memory die is wire bonded to (i) the package substrate and (ii) the random access memory die.

Clause 13. The packaging arrangement of clause 1, wherein the random access memory die is configured as dynamic random access memory.

Clause 14. A method comprising:

providing a package substrate;

coupling a random access memory die to the package substrate; and

coupling a serializing random access memory interface die to (i) the package substrate and (ii) the random access memory die.

Clause 15. The method of clause 14, wherein coupling the serializing random access memory interface die to (i) the package substrate and (ii) the random access memory die comprises placing the serializing random access memory interface die on the random access memory die.

Clause 16. The method of clause 14, wherein coupling the serializing random access memory interface die to (i) the package substrate and (ii) the random access memory die comprises placing the serializing random access memory interface die on the package substrate beside the random access memory die located on the package substrate.

Clause 17. The method of clause 14, wherein:

the random access memory die is a first random access memory die; and

the method further comprises coupling a second random access memory die to (i) the package substrate and (ii) the first random access memory die.

Clause 18. The method of clause 17, wherein coupling the second random access memory die to (i) the package substrate and (ii) the first random access memory die comprises placing the second random access memory die on the first random access memory die.

Clause 19. The method of clause 17, wherein coupling the second random access memory die to (i) the package substrate and (ii) the first random access memory die comprises placing the second random access memory die on the package substrate beside the first random access memory die located on the package substrate.

Clause 20. The method of clause 14, wherein coupling the random access memory die to the package substrate comprises flip-chip attaching the random access memory die to the package substrate.

Clause 21. The method of clause 14, wherein coupling the random access memory die to the package substrate comprises wire bonding the random access memory die to (i) the package substrate and (ii) the serializing random access memory interface die.

Clause 22. The method of clause 14, wherein coupling the serializing random access memory interface die to the package substrate comprises flip-chip attaching the serializing random access memory interface die to the package substrate.

Clause 23. The method of clause 14, wherein coupling the serializing random access memory interface die to the package substrate comprises wire bonding the serializing random access memory die to (i) the package substrate and (ii) the random access memory die.

The description may use the phrases “in an embodiment,” or “in embodiments,” which may each refer to one or more of the same or different embodiments. The phrase “in some embodiments” is used repeatedly. The phrase generally does not refer to the same embodiments; however, it may. The terms “comprising,” “having,” and “including” are synonymous, unless the context dictates otherwise. The phrase “A and/or B” means (A), (B), or (A and B). The phrase “A/B” means (A), (B), or (A and B), similar to the phrase “A and/or B.” The phrase “at least one of A, B and C” means (A), (B), (C), (A and B), (A and C), (B and C) or (A, B and C). The phrase “(A) B” means (B) or (A and B), that is, A is optional.

Although certain embodiments have been illustrated and described herein, a wide variety of alternate and/or equivalent embodiments or implementations calculated to achieve the same purposes may be substituted for the embodiments illustrated and described without departing from the scope of the present invention. This application is intended to cover any adaptations or variations of the embodiments discussed herein. Therefore, it is manifestly intended that embodiments in accordance with the present invention be limited only by the claims and the equivalents thereof.

What is claimed is:

1. A packaging arrangement comprising:
a package substrate;
a random access memory die coupled to the package substrate; and
a serializing random access memory interface die coupled to (i) the package substrate and (ii) the random access memory die.

2. The packaging arrangement of claim 1, wherein the serializing random access memory interface die is located on the random access memory die.

3. The packaging arrangement of claim 1, wherein the serializing random access memory interface die is located on the package substrate beside the random access memory die located on the package substrate.

4. The packaging arrangement of claim 1, wherein:
the random access memory die is a first random access memory die; and
the packaging arrangement further comprises a second random access memory die coupled to (i) the package substrate and (ii) the first random access memory die.

5. The packaging arrangement of claim 4, wherein the second random access memory die is located on the first random access memory die.

6. The packaging arrangement of claim 4, wherein the second random access memory die is located on the package substrate beside the first random access memory die located on the package substrate.

7. The packaging arrangement of claim 4, wherein the second random access memory die is directly coupled to the serializing random access memory interface die.

8. The packaging arrangement of claim 1, wherein the random access memory die is directly coupled to the serializing random access memory interface die.

9. The packaging arrangement of claim 1, wherein the random access memory die is flip-chip attached to the package substrate.

10. The packaging arrangement of claim 1, wherein the random access memory die is wire bonded to (i) the package substrate and (ii) the serializing random access memory interface die.

11. The packaging arrangement of claim 1, wherein the serializing random access memory interface die is flip-chip attached to the package substrate.

12. The packaging arrangement of claim 1, wherein the serializing random access memory die is wire bonded to (i) the package substrate and (ii) the random access memory die.

13. The packaging arrangement of claim 1, wherein the random access memory die is configured as dynamic random access memory.

14. A method comprising:
providing a package substrate;
coupling a random access memory die to the package substrate; and
coupling a serializing random access memory interface die to (i) the package substrate and (ii) the random access memory die.

15. The method of claim 14, wherein coupling the serializing random access memory interface die to (i) the package substrate and (ii) the random access memory die comprises placing the serializing random access memory interface die on the random access memory die.

16. The method of claim 14, wherein coupling the serializing random access memory interface die to (i) the package substrate and (ii) the random access memory die comprises placing the serializing random access memory interface die on the package substrate beside the random access memory die located on the package substrate.

17. The method of claim 14, wherein:
the random access memory die is a first random access memory die; and
the method further comprises coupling a second random access memory die to (i) the package substrate and (ii) the first random access memory die.

18. The method of claim 17, wherein coupling the second random access memory die to (i) the package substrate and (ii) the first random access memory die comprises placing the second random access memory die on the first random access memory die.

19. The method of claim 17, wherein coupling the second random access memory die to (i) the package substrate and (ii) the first random access memory die comprises placing the second random access memory die on the package substrate beside the first random access memory die located on the package substrate.

20. The method of claim 14, wherein coupling the random access memory die to the package substrate comprises flip-chip attaching the random access memory die to the package substrate.

21. The method of claim 14, wherein coupling the random access memory die to the package substrate comprises wire bonding the random access memory die to (i) the package substrate and (ii) the serializing random access memory interface die.

22. The method of claim 14, wherein coupling the serializing random access memory interface die to the package substrate comprises flip-chip attaching the serializing random access memory interface die to the package substrate.

23. The method of claim 14, wherein coupling the serializing random access memory interface die to the package substrate comprises wire bonding the serializing random access memory die to (i) the package substrate and (ii) the random access memory die.
